(19) United States
(12) Patent Application Publication
(10) Pub. No.: US 2023/0061514 A1
(43) Pub. Date: Mar. 2, 2023

(54) SUPERJUNCTION SEMICONDUCTOR DEVICE AND METHOD OF MANUFACTURING SAME

(71) Applicant: DB HiTek Co., Ltd., Bucheon-si (KR)

(72) Inventors: Jae Hyun KIM, Seoul (KR); Ji Eun LEE, Bucheon-si (KR); Young Kwon KIM, Haenam-gun (KR); Jong Min KIM, Seoul (KR)

(21) Appl. No.: 17/819,600

(22) Filed: Aug. 12, 2022

(30) Foreign Application Priority Data
Aug. 31, 2021 (KR) 10-2021-0115551

(51) Int. Cl. H01L 29/06; H01L 29/10; H01L 29/417

(52) U.S. Cl. CPC H01L 29/0634; H01L 29/0696; H01L 29/1095; H01L 29/41758

(57) ABSTRACT

Disclosed are a superjunction semiconductor device and a method of manufacturing the same. More particularly, the present disclosure relates to a superjunction semiconductor device and a method of manufacturing the same including one or more first conductivity type pillars in a ring region at least partially extending along a first direction, whereby it is possible to reduce electric field concentrations at a surface of the device, and thereby improve breakdown voltage characteristics and achieve an even or more even electric field distribution.

### CROSS REFERENCE TO RELATED APPLICATION

The present application claims priority to Korean Patent Application No. 10-2021-0115551, filed Aug. 31, 2021, the entire contents of which is incorporated herein for all purposes by this reference.

### BACKGROUND OF THE INVENTION

### 1. Technical Field

The present disclosure relates to a superjunction semiconductor device and a method of manufacturing the same. More particularly, the present disclosure relates to a superjunction semiconductor device and a method of manufacturing the same including first conductivity type pillars in a ring region that at least partially extend along a first direction, whereby it is possible to reduce surface electric field concentration(s) and thereby improve breakdown voltage characteristics and achieve a more even electric field distribution.

### 2. Description of the Related Art

In general, a high-voltage semiconductor device, such as a power metal-oxide-semiconductor field-effect transistor (MOSFET) and an insulated gate bipolar transistor (IGBT), includes a source and a drain that are on an upper surface and a lower surface of a drift region, respectively. In addition, the high-voltage semiconductor device includes a gate insulating layer on the upper surface of the drift region adjacent to the source, and a gate electrode on the gate insulating layer. When the high-voltage semiconductor device is on, the drift region provides a conductive path through which a drift current flows from the drain to the source. When the high-voltage semiconductor device is off, the drift region provides a depletion region that expands vertically in response to an applied reverse bias voltage.

The characteristics of the depletion region provided by the drift region determine the breakdown voltage of the high-voltage semiconductor device. In the above described high-voltage semiconductor device, to minimize conduction loss in the “on” state and to ensure fast switching speed, research has been conducted on reducing the resistance of the drift region serving as a conductive path in the “on” state. It is generally known in the art that the turn-on resistance of the drift region can be reduced by increasing the concentration of impurities in the drift region. However, when the concentration of impurities in the drift region increases, space charges increase in the drift region, thereby reducing the breakdown voltage of the device.

As a solution to this drawback, high-voltage semiconductor devices having a superjunction structure have been proposed to ensure a high breakdown voltage while reducing resistance in an “on” state.

FIG. 1 is a cross-sectional view illustrating a superjunction semiconductor device 9 according to the related art.

Hereinafter, the structure of the superjunction semiconductor device 9 according to the related art and the problems thereof will be described in detail with reference to the accompanying drawings.

Referring to FIG. 1, the superjunction semiconductor device 9 according to the related art has a structure in which, in a ring R region, each pillar region 930 having a first conductivity type in an epitaxial layer 910 (which may have a second conductivity type) extends in a second direction (e.g., perpendicular to a planar exposed surface of the epitaxial layer 910) in the same manner as a cell region C. Adjacent pillar regions 930 are spaced apart from each other along a first, orthogonal direction. With this, the electric field extends along each pillar region 930 in the second direction, and is indirectly transferred to the adjacent pillar regions 930 by the fringing field along the first direction. As a result, the distribution of the electric field extending along the first direction is relatively nonuniform, and the breakdown voltage characteristics of the device deteriorate due to a surface electric field concentration (e.g., at the surface of the epitaxial layer 910; also see FIG. 5).

In addition, when the distance in the first direction between the pillar regions 930 is longer than expected in the process of manufacturing the ring region R, the electric field cannot easily extend to the adjacent pillar regions 930 along the first direction; that is, the electric field is sensitively affected by the design of the ring region R. This inevitably increases adverse process variation effects.

### DOCUMENTS OF RELATED ART

Korean Patent Application Publication No. 10-2005-0052597, “Superjunction semiconductor device.”

### SUMMARY OF THE INVENTION

To solve the above problems, the present inventors have conceived a novel superjunction semiconductor device with an improved structure and a method of manufacturing the same.

Accordingly, the present disclosure has been made keeping in mind the above problems occurring in the related art, and an objective of the present disclosure is to provide a superjunction semiconductor device and a method of manufacturing the same including pillars and/or pillar portions in a ring region (“ring pillars and/or pillar portions”) that have a first portion extending along a second direction and a second portion extending along a first direction, so that adjacent ring pillars and/or pillar portions are connected to each other, whereby it is possible to easily extend an electric field (e.g., in an epitaxial layer of the device and/or along or at a surface of the epitaxial layer).

Another objective of the present disclosure is to provide a superjunction semiconductor device and a method of manufacturing the same including first conductivity type pillars and/or pillar portions in a ring region that are connected to each other along a first direction, whereby it is possible to reduce design sensitivity to variations in the ring region and thereby reduce adverse process variation effects.

Another objective of the present disclosure is to provide a superjunction semiconductor device and a method of manufacturing the same including first conductivity type pillars and/or pillar portions in a ring region that are connected to each other along the first direction, whereby it is possible to reduce an electric field concentration (e.g., at the surface of the epitaxial layer) through reduction or cancellation of electric field ripples between a first portion and a second portion (e.g., of the pillar or pillar portion in the ring region), and thereby improve breakdown voltage characteristics (e.g., of the device).

Another objective of the present disclosure is to provide a superjunction semiconductor device and a method of manufacturing the same including a first conductivity type pillar and/or pillar portion in a ring region having a second portion that gradually narrows in width (e.g., in the second direction) as a function of distance along the first direction, whereby it is possible to gradually reduce the strength of the electric field (e.g., at the surface of the epitaxial layer and/or in the ring region).

In order to achieve the above objectives, the present disclosure may be implemented by one or more embodiments having one or more of the following configurations.

According to one embodiment of the present disclosure, a superjunction semiconductor device may include a substrate; an epitaxial layer including a pillar region in the substrate; a gate insulating layer on the epitaxial layer (e.g., between adjacent pillars in the cell region of the substrate); and a gate electrode on the gate insulating layer. The pillar region may include a plurality of pillars that alternate with parts of the epitaxial layer along a first direction in a cell region and a ring region (e.g., of the substrate and/or the device), the pillars may include a plurality of cell pillar portions in the cell region and a plurality of ring pillars or pillar portions in the ring region, and each of the ring pillars or pillar portions may be connected to an adjacent one of the ring pillars or pillar portions.

According to another embodiment of the present disclosure, at least a subset of the ring pillars or pillar portions may have a first portion extending along a second direction; and a second portion extending along the first direction.

According to another embodiment of the present disclosure, at least a subset of the ring pillars or pillar portions may have a first portion extending along the second direction and having a predetermined height or depth; and a second portion on the first portion extending along the first direction.

According to another embodiment of the present disclosure, the second portion may include a plurality of second portions on a plurality of the first portions, and the second portions are spaced apart from each other.

According to another embodiment of the present disclosure, the second portion may cross into the cell region from the ring region.

According to another embodiment of the present disclosure, a superjunction semiconductor device may include a substrate; a drain electrode in contact with the substrate; a first conductivity type pillar and a second conductivity type epitaxial layer on the substrate; a gate insulating layer on the epitaxial layer; a gate electrode on the gate insulating layer; a first conductivity type body region in the epitaxial layer in a cell region; and a source in the body region. The pillar may include a cell pillar portion in the epitaxial layer in the cell region and a ring pillar or pillar portion in the ring region, and the ring pillar or pillar portion may be connected to an adjacent ring pillar or pillar portion.

According to another embodiment of the present disclosure, the superjunction semiconductor device may further include a body contact in the body region, in contact with the source.

According to another embodiment of the present disclosure, the ring pillar or pillar portion may have a first portion extending along the second direction and having a predetermined height or depth; and a plurality of second portions on the first portion, extending along the first direction and substantially orthogonal to the first portion.

According to another embodiment of the present disclosure, the epitaxial layer comprises a plurality of epitaxial layers, and the ring pillar or pillar portion may be in an uppermost one of the epitaxial layers.

According to another embodiment of the present disclosure, the ring pillar or pillar portion may be connected to the cell pillar portion.

According to another embodiment of the present disclosure, the second portion may gradually narrow in width (e.g., in the second direction) as it extends along the first direction.

According to another embodiment of the present disclosure, a method of manufacturing a superjunction semiconductor device may include forming a second conductivity type epitaxial layer on a substrate; forming a plurality of first conductivity type pillars in the epitaxial layer, the pillars being spaced apart from each other along a first direction; forming a gate insulating layer on the epitaxial layer; and forming a gate electrode on the gate insulating layer. The pillars in a cell region may be spaced apart from each other along the first direction and extend along a second direction, and at least a subset of the pillars in a ring region may extend along the first direction and the second direction.

According to another embodiment of the present disclosure, at least a subset of the pillars in the ring region may have a first portion extending along the second direction and having a predetermined height or depth; and a second portion on the first portion and extending along the first direction.

According to another embodiment of the present disclosure, forming the pillars may include forming first portions having a predetermined height or depth in the epitaxial layer, spaced apart from each other along the first direction, and extending along the second direction; and forming second portions on the first portions, extending along the first direction and connected to adjacent ones of the first portions.

According to another embodiment of the present disclosure, the method may further include forming a body region in the epitaxial layer in the cell region; forming one or more sources in the body region; and forming a body contact in the body region.

According to another embodiment of the present disclosure, a method of manufacturing a superjunction semiconductor device may include forming a plurality of second conductivity type epitaxial layers on a substrate; forming an implant layer including a first conductivity type impurity region on each of the epitaxial layers; forming a first conductivity type pillar in the epitaxial layers by diffusing the impurity region in the implant layer; forming a gate insulating layer on the epitaxial layers; and forming a gate electrode on the gate insulating layer. The pillar may be connected to a second portion in a ring region.

According to another embodiment of the present disclosure, the impurity regions in the implant layer on each of the epitaxial layers other than an uppermost one of the epitaxial layers in the ring region are spaced apart from each other along a first direction; and the impurity region in the implant layer on the uppermost epitaxial layer in the ring region extends along the first direction.

According to another embodiment of the present disclosure, forming the implant layer on each of the epitaxial layers other than the uppermost epitaxial layer comprises forming a plurality of first conductivity type impurity regions spaced apart from each other along the second direction.

According to another embodiment of the present disclosure, the method may further include forming a cell pillar portion in the cell region; forming a first conductivity type body region connected to the cell pillar portion; and forming a second conductivity type source in the body region.

The above configurations one or more of the following effects.

The ring pillar or pillar portion in the ring region has a first portion extending along the second direction and a second portion extending along the first direction so that adjacent ring pillars or pillar portions are connected to each other, whereby it is possible to facilitate extension of an electric field (e.g., through the epitaxial layer or along a surface of the epitaxial layer in the ring region).

Furthermore, the first conductivity type pillars in the ring region are connected to each other along the first direction, whereby it is possible to reduce design sensitivity to variations in the ring region and thereby reduce adverse process variation effects.

Furthermore, the first conductivity type pillars in the ring region are connected to each other along the first direction, whereby it is possible to reduce electric field concentrations along the surface of the epitaxial layer in the ring region through cancellation of electric field ripples between a first portion and a second portion (e.g., of a pillar and/or pillar portion in the ring region), and thereby improve breakdown voltage characteristics (e.g., of the device).

Furthermore, the first conductivity type pillar in the ring region may have a second portion that gradually narrows in width (e.g., in the second direction) as it extends along the first direction, whereby it is possible to gradually reduce the strength of an electric field (e.g., in the ring region).

Meanwhile, the effects of the present disclosure are not limited to the effects described above, and other effects not stated directly can be understood from the following description and claims.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a superjunction semiconductor device according to the related art;

FIG. 2 is a plan view illustrating the structure of a superjunction semiconductor device according to an embodiment of the present disclosure;

FIG. 3 is an enlarged plan view illustrating a ring region in the superjunction semiconductor device illustrated in FIG. 2;

FIG. 4 is a cross-sectional view illustrating part of the structure of the superjunction semiconductor device illustrated in FIG. 2;

FIG. 5 is a graph illustrating a comparison of a surface electric field in a first direction between the superjunction semiconductor device illustrated in FIG. 2 and the superjunction semiconductor device according to the related art; and

FIGS. 6 to 13 are cross-sectional views illustrating a method of manufacturing a superjunction semiconductor device according to an embodiment of the present disclosure.

### DETAILED DESCRIPTION OF THE INVENTION

Hereinafter, embodiments of the present disclosure will be described in more detail with reference to the accompanying drawings. The embodiments of the present disclosure can be modified in various forms. Therefore, the scope of the disclosure should not be construed as being limited to the following embodiments, but should be construed on the basis of the descriptions in the appended claims. The embodiments of the present disclosure are provided for completeness of the disclosure and to fully convey the scope of the present disclosure to those skilled in the art.

As used herein, when an element (or layer) is referred to as being on another element (or layer), it can be directly on the other element, or one or more intervening elements or layers may be therebetween. In contrast, when an element is referred to as being directly on or above another element, no intervening elements are therebetween. Further, the terms “on,” “above,” “below,” “upper,” “lower,” “one side,” “side surface,” etc. are used to describe one element's relationship to one or more other elements illustrated in the drawings.

While the terms “first,” “second,” “third,” etc. may be used herein to describe various items such as various elements, regions and/or parts, these items should not be limited by these terms.

When a certain embodiment may be implemented differently, a specific process order may be performed differently from the described order. For example, two consecutive processes may be performed substantially at the same time or performed in an order opposite to the described order.

The term “metal-oxide-semiconductor (MOS)” used herein is a general term. “M” is not limited to only metal and may include various types of conductors. “S” may be a substrate or a semiconductor structure. “O” is not limited to only oxide and may include various types of organic or inorganic insulating or dielectric materials.

In addition, the conductivity type of a doped region or element may be defined as “P-type” or “N-type”according to the main carrier characteristics. However, this is only for convenience of description, and the technical spirit of the present disclosure is not limited to the above-mentioned examples. For example, “P-type” or “N-type” may be replaced with the more general terms “first conductivity type” or “second conductivity type” hereinafter, where “first conductivity type” may refer to P type, and “second conductivity type” may refer to N type.

It should be further understood that the terms “heavily doped” and “lightly doped” representing the doping concentration of an impurity region may refer to the relative concentration of dopant element(s) in the impurity region.

In addition, it should be understood that “first direction” may refer to an x-axis direction in the drawings, and “second direction” may refer to a y-axis direction orthogonal to the x-axis direction.

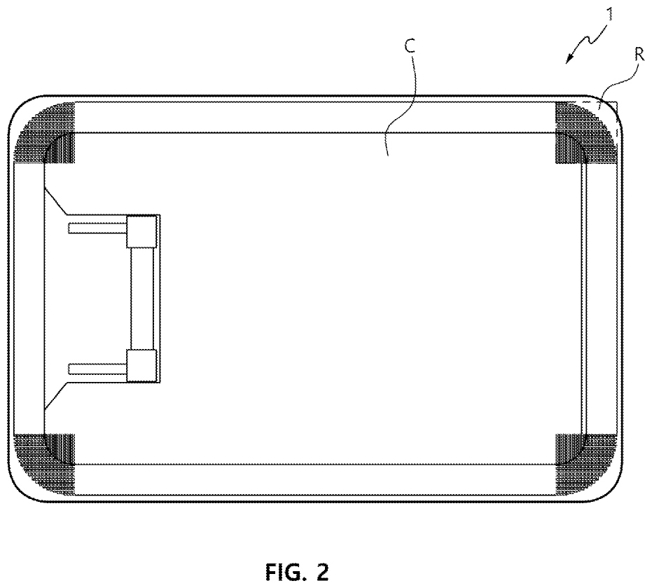

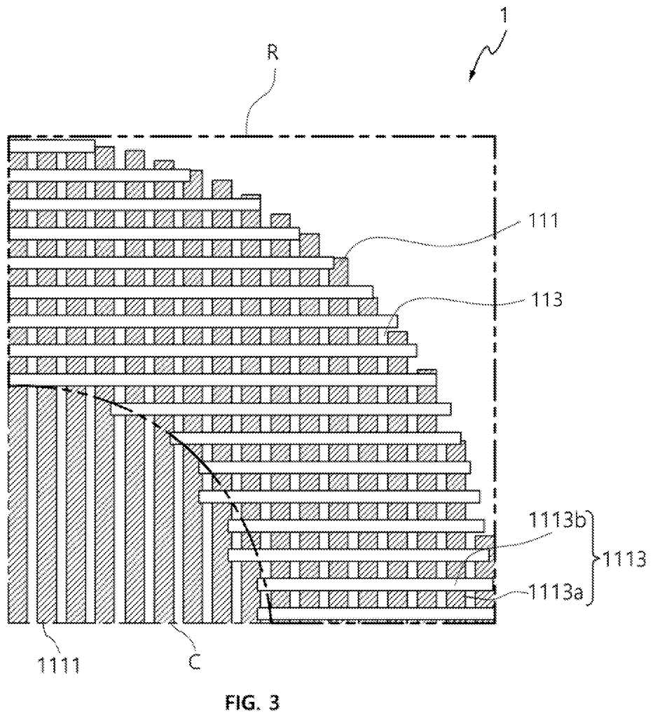

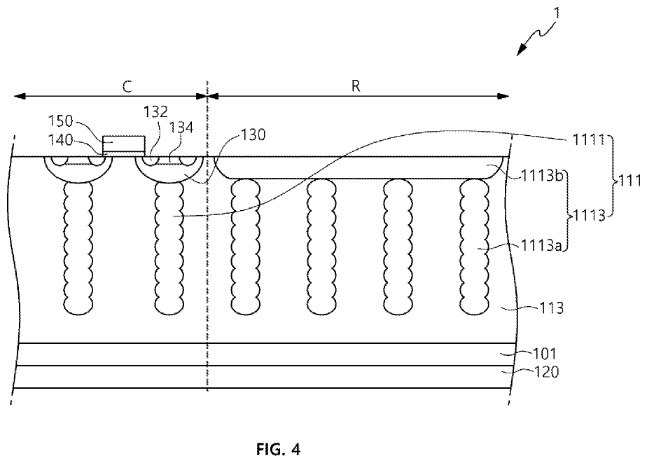

FIG. 2 is a plan view illustrating the structure of a superjunction semiconductor device 1 according to an embodiment of the present disclosure. FIG. 3 is an enlarged plan view illustrating a ring region R in the superjunction semiconductor device 1 illustrated in FIG. 2. FIG. 4 is a cross-sectional view illustrating part of the structure of the superjunction semiconductor device 1 illustrated in FIG. 2.

Hereinafter, the superjunction semiconductor device 1 according to embodiments of the present disclosure will be described in detail with reference to the accompanying drawings.

Referring to FIGS. 2 to 4, the present disclosure relates to a superjunction semiconductor device 1 and, more particularly, to a superjunction semiconductor device 1 including a plurality of first conductivity type pillars 1113a-b in the ring region Rat least partially extending in first direction, whereby it is possible to reduce surface electric field concentration and thereby improve breakdown voltage characteristics (e.g., of the superjunction semiconductor device) and to achieve a more even distribution of an electric field (e.g., in the ring region R).

The superjunction semiconductor device 1 according to the present disclosure includes a cell region C serving as an active region; and a ring region R serving as a termination region that surrounds the cell region C.

Describing the structure of the superjunction semiconductor device 1 according to the present disclosure, a substrate 101 in the lower part of FIG. 4 may comprise a silicon substrate and/or a germanium substrate, and may include a bulk wafer or an epitaxial layer. The substrate 101 may be, for example, a heavily doped second conductivity type substrate.

An epitaxial layer 113 having a second conductivity type is on the substrate 101. The epitaxial layer 113 may include a plurality of pillars 111 having a first conductivity type, alternating with parts of the epitaxial layer 113 along the first direction in both the cell region C and the ring region R. Each of the pillars 111 may extend a predetermined depth substantially in a vertical direction in the epitaxial layer 113 and may have substantially planar-shaped surfaces. Alternatively, the surfaces on opposite sides of the pillars 111 may be curved in opposite directions. However, the scope of the present disclosure is not limited to specific examples. The epitaxial layer 113 is lightly doped with second conductivity type impurities and may be, for example, formed by epitaxial growth, and a detailed description thereof will be provided later.

Hereinafter, for convenience of explanation, a portion of a pillar 111 in the cell region C will be referred to as a cell pillar portion 1111, and a pillar 111 or portion thereof in the ring region R will be referred to as a ring pillar or pillar portion 1113. In other words, the cell pillar portion 1111 and the ring pillar or pillar portion 1113 may be individual or separate pillar configurations, or a single pillar 111 may be a single configuration including a cell pillar portion 1111 in the cell region C and a ring pillar or pillar portion 1113 in the ring region R, but is not limited thereto. Cell pillar portions 1111 may be spaced apart from each other in the first direction in the cell region C and may have a stripe, line or elongated oval or rectangular shape in a plan view that extends in the second direction.

In addition, referring to FIG. 3, the ring pillars or ring pillar portions 1113 in the ring region R extend along the first direction at least partially and extend along the second direction at least partially. In more detail, at least portions of the ring pillars or pillar portions 1113 in the ring region R may extend along the second direction and may be spaced apart from each other along the first direction, and the at least portions of the ring pillars or pillar portions 1113 may extend along the first direction at a specific height so that adjacent ring pillars or pillar portions 1113 in the first direction are connected to each other (e.g., electrically and/or physically). For example, each of the ring pillars or pillar portions 1113 may have a first portion 1113a extending along the second direction to a predetermined height or depth, and a second portion 1113b on an upper portion or surface of the first portion 1113a along the first direction, so that the adjacent ring pillars or pillar portions 1113 having the same y-coordinate(s) are connected to each other (e.g., electrically and/or physically).

In addition, it is preferable that a plurality of second portions 1113b are on the first portions 1113a of the ring pillars or pillar portions 1113, spaced apart from each other in the second direction. In other words, a plurality of ring pillars or pillar portions 1113 may have a plurality of sections connected to each other. Each of the second portions 1113b may be connected at the same height or depth in the epitaxial layer 113 to the ring pillars or pillar portions 1113a in the ring region C. The second portions 1113b may cross into the cell region C and may contact one or more cell pillar portions 1111, but is not limited thereto.

As will be described in detail below, when the pillars 111 and the epitaxial layer 113 are formed by forming a plurality of alternating second conductivity type epitaxial layers and first conductivity type implant or diffusion layers in a predetermined region on each of the epitaxial layers, then performing a diffusion process (e.g., by heating), the second portions 1113b of the ring pillars or pillar portions 1113 may be formed by implanting or depositing a first conductivity type impurity region or layer in or on the uppermost epitaxial layer that extends along the first direction and are spaced apart from each other in the second direction.

Hereinafter, the structure of a superjunction semiconductor device 9 according to the related art and the problems thereof, and the structure of the superjunction semiconductor device 1 according to the present disclosure for solving the problems will be described.

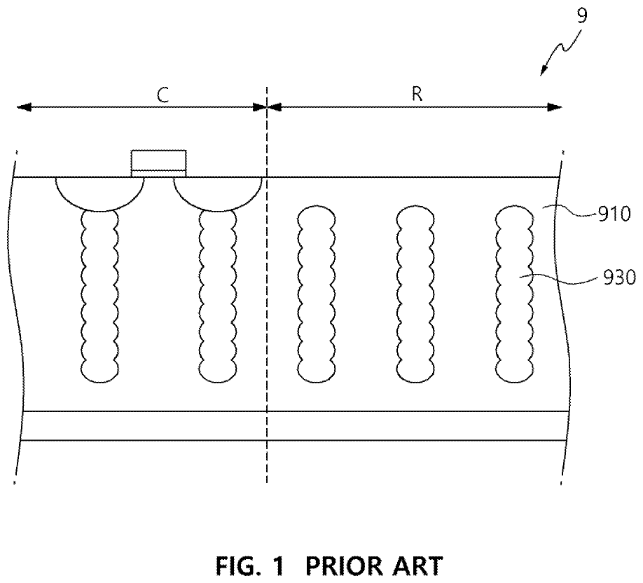

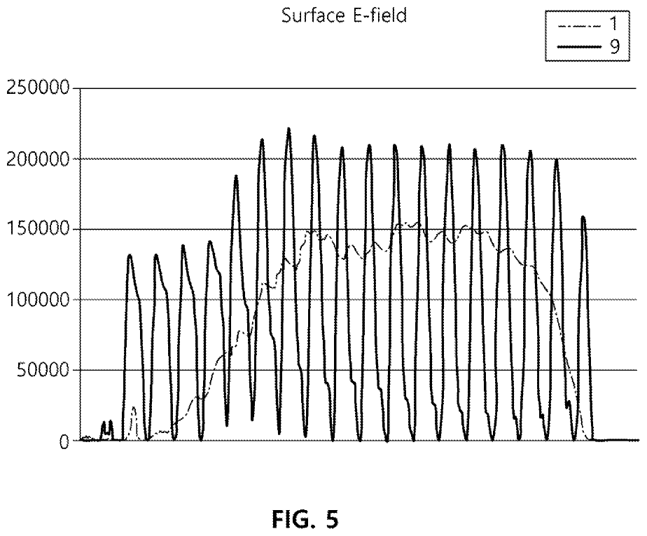

Referring to FIG. 1, the superjunction semiconductor device 9 according to the related art has a structure in which, in a ring R region, each pillar region 930 having a first conductivity type in an epitaxial layer 910 (which may have a second conductivity type) extends along a second direction (e.g., perpendicular to a planar exposed surface of the epitaxial layer 910) in the same manner as a cell region C. Adjacent pillar regions 930 are spaced apart from each other along a first, orthogonal direction. With this, the electric field extends along each pillar region 930 in the second direction, and is indirectly transferred to the adjacent pillar regions 930 by the fringing field along the first direction. As a result, the distribution of the electric field extending along the first direction is relatively nonuniform, and the breakdown voltage characteristics of the device are also deteriorated due to surface electric field concentration (e.g., at the surface of the epitaxial layer 910; also see FIG. 5).

In addition, when the distance in the first direction between the pillar regions 930 is longer than expected in the process of manufacturing the ring region R, the electric field cannot easily extend to the adjacent pillar regions 930 along the first direction, that is, the electric field is sensitively affected by the design of the ring region R. This inevitably increases adverse process variation effects.

FIG. 5 is a graph illustrating a comparison of a surface electric field in the first direction between the superjunction semiconductor device 1 illustrated in FIG. 2 and the superjunction semiconductor device 9 according to the related art.

In order to solve the above problems, referring to FIGS. 2 to 4, the superjunction semiconductor device 1 according to the present disclosure includes ring pillars or pillar portions 1113 in the ring region R that have a first portion 1113a extending along the second direction and a second portion 1113b extending along the first direction. With such a structure, it is possible to extend the electric field in the first direction and the second direction, reduce sensitivity to the design of the ring region R, and reduce surface electric field concentration(s), thereby improving breakdown voltage characteristics. Referring to FIG. 5, it is revealed that in the case of the superjunction semiconductor device 1 according to the present disclosure, the maximum value (e.g., of the surface electric field) is significantly reduced, as are ripples in the surface electric field, as compared to the device 9 according to the related art. In addition, the ring pillar or pillar portion 1113 may include a second portion 1113b that gradually narrows in width in the second direction as it extends along the first direction, so that the strength of the electric field (e.g., as a function of increasing distance from the cell region C) is gradually reduced.

Describing again the structure of the present disclosure with reference to FIGS. 2 to 4, a drain electrode 120 may be on an underside of the substrate 101. In addition, a first conductivity type body region 130 having a predetermined depth is in an upper region of the epitaxial layer 113 in the cell region C. The body region 130 may have a lower portion or surface connected to an upper end or surface of each of the cell pillar portions 1111.

One or more sources 132 are in the body region 130. The source 132 may comprise a second conductivity type heavily doped impurity region. One or two sources 132 may be in the body region 130, but are not limited thereto. For example, when the two sources 132 are in the body region 130, current paths may respectively pass through the epitaxial layer 113 at opposite sides of the cell pillar portions 1111. In addition, a body contact 134 may be in the body region 130 at a position adjacent to the source(s) 132 or in contact with one or more of the sources 132. The body contact 134 comprises a first conductivity type heavily doped impurity region.

When a voltage according to an avalanche current of a device such as the superjunction semiconductor device 1 approaches a built-in electrical potential of the junction of the source 132 and the body region 130, a parasitic bipolar junction transistor (BJT) may turn on, which may cause an unclamped inductive switch (UIS) error in the device. The heavily doped body contact 134 may remove or prevent this UIS error. The source 132 and the body contact 134 are not in an edge region or the ring region R, but are preferably only in the cell region C.

A gate insulating layer 140 is on the epitaxial layer 113 in the cell region C. A gate electrode 150, which will be described later, may be on the gate insulating layer 140. The gate insulating layer 140 may comprise a silicon oxide layer (e.g., thermally-grown silicon dioxide), a high-k dielectric layer, or a combination thereof. In addition, the gate insulating layer 140 may be formed by thermal growth, atomic layer deposition (ALD), chemical vapor deposition (CVD), or physical vapor deposition (PVD; e.g., sputtering or evaporation).

The gate electrode 150 is on the gate insulating layer 140 in the cell region C. For example, the gate electrode 150 may be substantially flat on the gate insulating layer 140 (e.g., both the gate electrode 150 and the gate insulating layer 140 may have a substantially planar interface). A channel region may be turned on or off in response to a gate voltage applied to the gate electrode 150. The gate electrode 150 may comprise a conductive polysilicon, a metal, a conductive metal nitride, or a combination thereof, and may be formed by CVD, PVD, ALD, metalorganic ALD (MOALD), or metalorganic CVD (MOCVD).

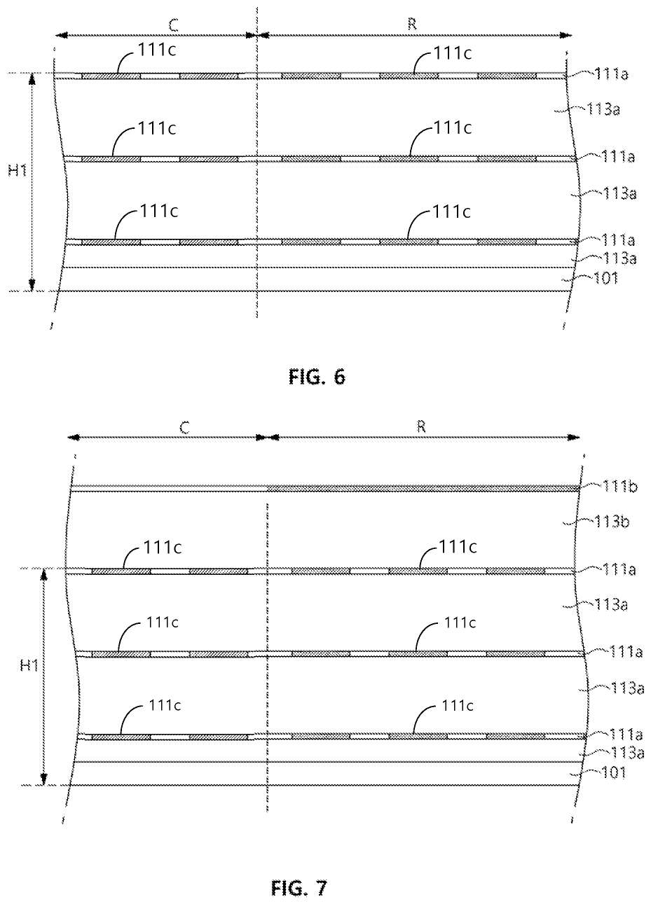

FIGS. 6 to 13 are cross-sectional views illustrating a method of manufacturing a superjunction semiconductor device according to one or more embodiments of the present disclosure.

Hereinafter, the method of manufacturing the superjunction semiconductor device according to the present disclosure will be described in detail with reference to the accompanying drawings.

A second conductivity type epitaxial layer 113, and a cell pillar portion 1111, and a ring pillar or pillar portion 1113 in the epitaxial layer 113, are formed on a substrate 110.

Referring to FIG. 6, for example, a plurality of second conductivity type epitaxial layers 113a and a plurality of implant or diffusible dopant layers 111a, each including a plurality of first conductivity type impurity regions 111c, are alternatingly formed on the substrate 101 to a predetermined height (hereinafter, referred to as a first height H1). The epitaxial layers 113a may be formed by epitaxial growth or epitaxial deposition (e.g., of silicon on a silicon substrate 101), the implant or diffusible dopant layers 111a may be formed by blanket deposition (e.g., by ALD, CVD or PVD) or epitaxial growth/deposition (e.g., of silicon on the exposed epitaxial layer 113a), and the impurity regions 111c may be formed by conventional ion implantation. The first conductivity type impurity regions 111c in the implant layers 111a on each of the epitaxial layers 113a may be in both the cell region C and the ring region R, and may extend in the first or second direction.

Then, referring to FIG. 7, an additional second conductivity type epitaxial layer 113b is formed on the exposed or uppermost implant or diffusible dopant layer 111a (e.g., by epitaxial growth or epitaxial deposition), and then an additional implant layer 111b is formed on the additional epitaxial layer 113b (e.g., by blanket deposition or epitaxial growth/deposition). An implant or diffusible dopant region (shown by diagonal hatching) may be formed in the additional implant layer 111b in the ring region R by conventional ion implantation. Alternatively, the implant or diffusible dopant region 111b may be formed in the ring region R by conventional ion implantation into the exposed surface of the additional epitaxial layer 113b. The implant or diffusible dopant region 111b in or on the additional epitaxial layer 113b may comprise a first conductivity type impurity and extend in the first or second direction (e.g., the implant or diffusible dopant region 111b may have [i] a length that is orthogonal to a length of the impurity regions 111c and [ii] a width that is orthogonal to a width of the impurity regions 111c). Preferably, the first conductivity type impurity regions 111c in the implant layers 111a extends along a first direction, and the first conductivity type impurity region 111b extends in a second, orthogonal direction.

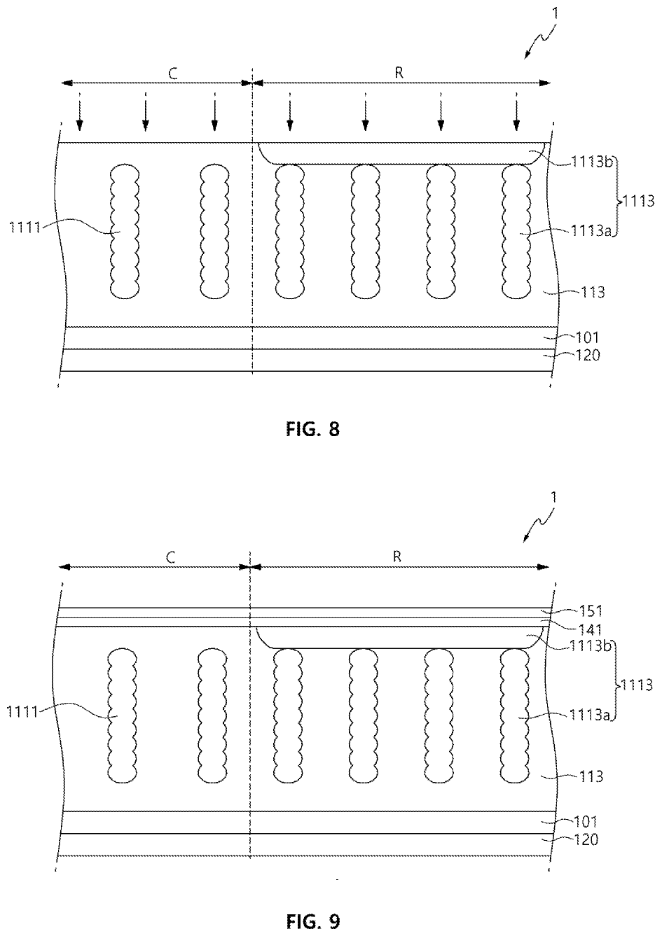

Thereafter, referring to FIG. 8, the cell pillar portions 1111 and the ring pillars and/or pillar portions 1113 are formed by a diffusion process (e.g., comprising heating at least the epitaxial layer 113 to a diffusion and/or dopant/impurity activation temperature for a length of time sufficient to diffuse and/or activate the dopant/impurity).

After the pillars 111 are formed, a gate insulating layer 140 and a gate electrode 150 are formed. Referring to FIG. 9, for example, an insulating layer 141 is grown or blanket-deposited on the epitaxial layer 113 in the cell region C and the ring region R, and a gate layer 151 comprising, for example, conductive polysilicon, is blanket-deposited on the insulating layer 141.

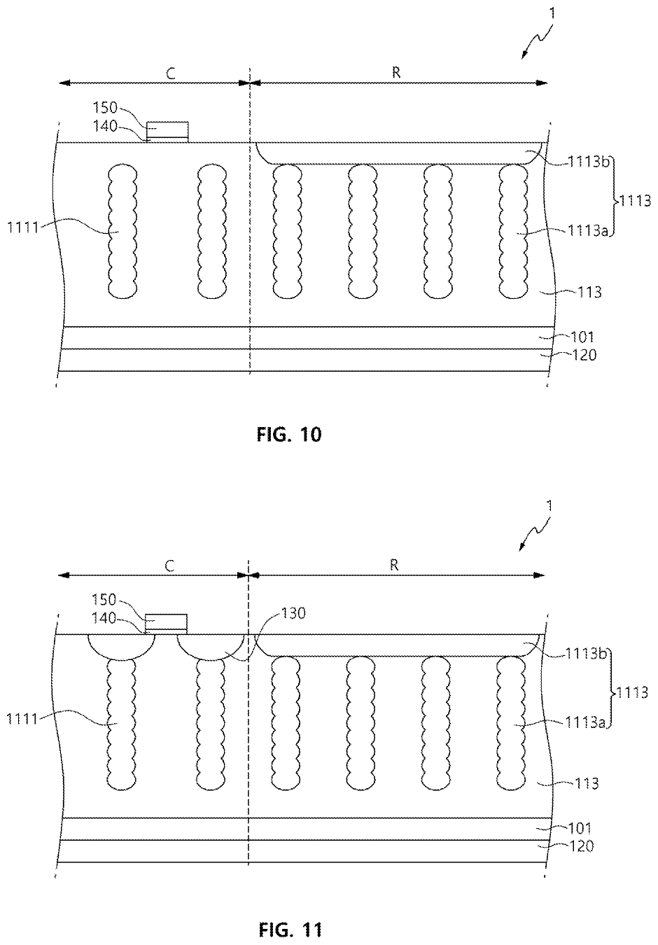

Then, referring to FIG. 10, the gate layer 151 and the insulating layer 141 are successively etched using a mask pattern (not illustrated) on the locations of the gate insulating layers 140 and the gate electrodes 150. As a result, the gate insulating layer 140 and the gate electrode 150 are formed. The gate electrode 150 may have a strip, an elongated oval, or an elongated rectangle shape, and may be over spaces between adjacent pillar portions 1111 in the cell region C.

Thereafter, referring to FIG. 11, a plurality of body regions 130 are formed by, for example, implanting first conductivity type impurities in an upper region or uppermost surface of the epitaxial layer 113 above the cell pillar portions 1111 using the gate electrodes 150 (in part) as a mask. In an alternative process, the second portions 1113b of the ring pillars and/or pillar portions 1113 may be formed at the same time as the body regions 130, by the same process as the body regions 130, thereby simplifying the method of manufacturing.

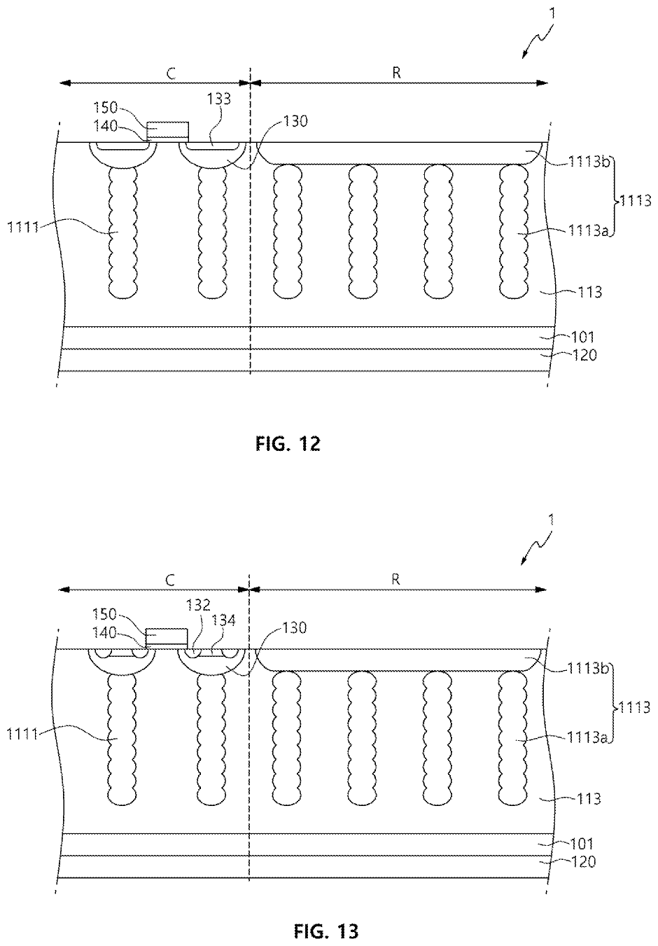

Thereafter, referring to FIG. 12, a second conductivity type impurity region 133 (e.g., for forming one or more sources 132; see FIG. 13) may be formed by implanting heavily doped second conductivity type impurities in the body region 130 (e.g., using a patterned photoresist mask and the gate electrode 150 to block unimplanted regions of the epitaxial layer 113).

Finally, referring to FIG. 13, a body contact 134 is formed in the body region 130, adjacent to or in contact with the impurity region 133, resulting in formation of source(s) 132. The body contact 134 may overlap the second conductivity type impurity region 133 and may be formed by implanting first conductivity type impurities in the body region 130 using a mask pattern (not illustrated), but is not limited thereto.

The foregoing detailed descriptions may be merely an example of the prevent disclosure. Also, the inventive concept is explained by describing various embodiments and can be used in various combinations, modifications, and environments. That is, the inventive concept may be amended or modified without departing from the scope of the technical idea and/or knowledge in the art. The foregoing embodiments are for illustrating implementations of the technical idea(s) of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A superjunction semiconductor device, comprising:
a substrate;
an epitaxial layer including a pillar region on the substrate;
a gate insulating layer on the epitaxial layer; and
a gate electrode on the gate insulating layer,
wherein the pillar region comprises a plurality of pillars alternating with parts of the epitaxial layer along a first direction in a cell region and a ring region,
the pillars comprise a plurality of cell pillar portions in the cell region and a plurality of ring pillars and/or pillar portions in the ring region, and
each of the ring pillars and/or pillar portions is connected to an adjacent one of the ring pillars or pillar portions.

2. The superjunction semiconductor device of claim 1, wherein at least a subset of the ring pillars or pillar portions comprises:
a first portion extending along a second direction; and
a second portion extending along the first direction.

3. The superjunction semiconductor device of claim 1, wherein at least a subset of the ring pillars or pillar portions has:
a first portion extending along a second direction and having a predetermined height or depth; and
a second portion on the first portion, extending along the first direction.

4. The superjunction semiconductor device of claim 3, wherein the second portion comprises a plurality of second portions on a plurality of the first portions, and the second portions are spaced apart from each other.

5. The superjunction semiconductor device of claim 4, wherein the second portions cross into the cell region from the ring region.

6. A superjunction semiconductor device, comprising:
a substrate;
a drain electrode in contact with the substrate;
a first conductivity type pillar and a second conductivity type epitaxial layer on the substrate;
a gate insulating layer on the epitaxial layer;
a gate electrode on the gate insulating layer;
a first conductivity type body region in the epitaxial layer in a cell region; and
a source in the body region,
wherein the pillar comprises a cell pillar portion in the epitaxial layer in the cell region and a ring pillar or pillar portion in the ring region, and
the ring pillar or pillar portion is connected to an adjacent ring pillar or pillar portion.

7. The superjunction semiconductor device of claim 6, further comprising a body contact in the body region, in contact with the source.

8. The superjunction semiconductor device of claim 6, wherein the ring pillar or pillar portion has:
a first portion extending along a second direction and having a predetermined height or depth; and
a plurality of the second portions on the first portion, extending along a first direction and substantially orthogonal to the first portion.

9. The superjunction semiconductor device of claim 8, wherein the epitaxial layer comprises a plurality of epitaxial layers, and the ring pillar or pillar portion is in an uppermost one of the epitaxial layers.

10. The superjunction semiconductor device of claim 8, wherein the ring pillar or pillar portion is connected to the cell pillar portion.

11. The superjunction semiconductor device of claim 8, wherein the second portion gradually narrows in width as it extends along the first direction.

12. A method of manufacturing a superjunction semiconductor device, the method comprising:
forming a second conductivity type epitaxial layer on a substrate;
forming a plurality of first conductivity type pillars in the epitaxial layer, the pillars being spaced apart from each other along a first direction;
forming a gate insulating layer on the epitaxial layer; and
forming a gate electrode on the gate insulating layer,
wherein the pillars in a cell region are spaced apart from each other along the first direction and extend along a second direction, and
at least a subset of the pillars in a ring region extend along the first direction and the second direction.

13. The method of claim 12, wherein at least the subset of the pillars in the ring region have:
a first portion extending along the second direction and having a predetermined height or depth; and
a second portion on the first portion and extending along the first direction.

14. The method of claim 12, wherein forming the pillars comprises:
forming first portions having a predetermined height or depth in the epitaxial layer, spaced apart from each other along the first direction, and extending along the second direction; and
forming second portions in the ring region on the first portions, extending along the first direction and connected to adjacent ones of the first portions.

15. The method of claim 12, further comprising:
forming a body region in the epitaxial layer in the cell region;
forming one or more sources in the body region; and
forming a body contact in the body region.

16. A method of manufacturing a superjunction semiconductor device, the method comprising:
forming a plurality of second conductivity type epitaxial layers on a substrate;
forming an implant layer including a first conductivity type impurity region on each of the epitaxial layers;
forming a first conductivity type pillar in the epitaxial layers by diffusing the impurity region in the implant layer;
forming a gate insulating layer on the epitaxial layers; and
forming a gate electrode on the gate insulating layer,
wherein the pillar is connected to a second portion in a ring region.

17. The method of claim 16, wherein:
the impurity regions in the implant layer on each of the plurality of epitaxial layers other than an uppermost one of the epitaxial layers in the ring region are spaced apart from each other along a first direction; and
the impurity region in the implant layer on the uppermost epitaxial layer in the ring region extends along the first direction.

18. The method of claim 17, wherein forming the implant layer on each of epitaxial layers other than the uppermost epitaxial layer comprises forming a plurality of the first conductivity type impurity regions spaced apart from each other along the second direction.

19. The method of claim 18, further comprising:
forming a cell pillar portion in the cell region;
forming a first conductivity type body region connected to the cell pillar; and
forming a second conductivity type source in the body region.
